(19) United States
(12) Patent Application Publication
(10) Pub. No.: US 2017/0215308 A1
(43) Pub. Date: Jul. 27, 2017

(54) Component For Electromagnetic Interference Suppression And Method For Producing A Component For Electromagnetic Interference Suppression

(71) Applicant: Würth Elektronik eiSos GmbH & Co. KG, Waldenburg (DE)

(72) Inventors: Steffen MÜTSCH, Schöntal-Bieringen (DE); Florian Roider, Beilstein (DE); Frank Gräbner, Nordhausen (DE)

(21) Appl. No.: 15/413,833

(22) Filed: Jan. 24, 2017

(30) Foreign Application Priority Data
Jan. 26, 2016 (DE) 102016201061.1

(51) Int. Cl. H05K 9/00; H01F 41/02; C01G 49/00; H01F 1/36

(52) U.S. Cl. CPC H05K 9/0081; H01F 1/36; H01F 41/0246; C01G 49/0036; C01P 2002/76; C01P 2002/60; C01P 2006/42

(57) ABSTRACT

The invention relates to a component for electromagnetic interference suppression, consisting of ferrite powder with a hexagonal crystal structure, wherein the ferrite powder has the composition SrₓFe_{y}C_{12-y}O_{z}, C being a transition metal from the periodic table of elements.

### BACKGROUND

The invention relates to a component for electromagnetic interference suppression, consisting of ferrite powder with a hexagonal crystal structure. The invention also relates to a method for producing a component for electromagnetic interference suppression.

Published German patent application DE 10 2014 0.01 616 A1 discloses the use of ferrite materials with a hexagonal crystal structure in components for electromagnetic interference suppression. The ferrite materials may contain strontium, barium and cobalt. The use of such ferrite materials with a hexagonal crystal structure in the form of a laminate, in the form of housings, and as sintered bodies, is proposed. Application in a frequency range of between 1 GHz and 100 GHz is described.

### SUMMARY

Objects of the invention are to provide an improved component for electromagnetic interference suppression, consisting of ferrite powder with a hexagonal crystal structure, and to provide a method for producing such a component.

To this end, according to the invention, a component for electromagnetic interference suppression having the features of Claim 1 and a method for producing such a component having the features of Claim 7 are provided. Advantageous refinements of the invention are specified in the dependent claims.

According to the invention, a component for electromagnetic interference suppression, consisting of ferrite powder with a hexagonal crystal structure, is provided, wherein the ferrite powder has the composition SrₓFe_{y}C_{12-y}O_{z}, C being a transition metal from the periodic table of elements.

Such a composition of the ferrite powder has been found particularly advantageous in relation, to processability of the ferrite powder and in relation to a frequency range of the absorption of the ferrite powder. For example, z can be 19 so that the ferrite powder has the composition SrₓFe_{y}C_{12-y}O₁₉.

In one refinement of the invention, C is a transition metal from the 4th, 5th, 9th, or 10th group of the periodic table of elements.

In one refinement of the invention, x lies between 0.9 and 1, and is in particular 1.

In one refinement of the invention, y lies between 0.1 and 0.8, in particular between 0.2 and 0.5, and is preferably between 0.3 and 0.4.

In one refinement of the invention, a grain size of the ferrite powder lies between 50 μm and 100 μm advantageously between 75 μm and 100 μm.

The electromagnetic properties of the ferrite powder can be influenced by means of the grain size of the ferrite powder. A grain size in the range of between 75 μm and 100 μm is in this case particularly advantageous for the electromagnetic properties. In order to improve the process reliability during production of the component, it may nevertheless be advantageous to reduce the grain size of the powder to a value of between 50 μm and 75 μm.

In one refinement of the invention, the component is formed as a half-shell, plate, sleeve, ring, or as a block with passage openings.

A component according to the indention may he formed into essentially any desired shape. In particular, the ferrite powder is either applied as a coating or mixed with other materials, which are likewise constituent of the component. It is particularly advantageous to sinter the ferrate powder in order to produce the component according to the invention.

For example, the components according to the invention may be pressed from the ferrate powder. A dry-pressing method may be used in this case. The pressed shapes are then compacted by sintering. The sintering may, for example, be carried out at from 1100° C. to 1400° C.

In a method according to the invention, the production of the ferrite powder is carried out from a mixture of Sr carbonate or Sr oxide, Fe oxide and oxides of transition metals.

In one refinement of the invention, heating of the mixture to a temperature of between 1100° C. and 1400° C. is provided.

By such calcination, a solid-state reaction, in which the hexagonal ferrite is formed, takes place in the temperature range between 1100° C. and 1400° C.

In one refinement of the invention, the mixture is ground in order to adjust the grain size. Advantageously, the grain size is adjusted during the grinding to a value of between, 50 μm and 100 μm, a relatively large grain size, i.e. for example in the range of between 75 μm and 100 μm, having been found to be advantageous for the electromagnetic properties of the ferrite powder. The ferrate powder may be dry-pressed in order to produce the component. In order to improve the process reliability during the sintering, it may be advantageous to reduce the grain size to a value of between 50 μm and 75 μm.

### BRIEF DESCRIPTION OF THE DRAWINGS

Other features and advantages of the invention may be found in the claims and the following description of preferred embodiments of the invention in conjunction with the drawings. Individual features of the different embodiments represented and described may be combined with one another in any desired way without departing from the scope of the invention. In the drawings:

FIG. 1 shows a view of a component according to the invention according to a first embodiment, obliquely from above,

FIG. 2 shows a view of a component according to the invention, according to a second embodiment, obliquely from above,

FIG. 3 shows a view of a component according to the invention according to a third embodiment, obliquely from above,

FIG. 4 shows a view of a component according to the invention according to a fourth embodiment, obliquely from above,

FIG. 5 shows a schematic representation of the structure of a grain of the ferrite powder in the component according to the invention,

FIG. 6 shows a schematic representation of a first experimental setup with a component according to the invention,

FIG. 7 shows a diagram of the result of a reference measurement with the experimental setup of FIG. 6 without the component according to the invention,

FIG. 8 shows a measurement with the experimental setup of FIG. 6, including the component according to the invention,

FIG. 9 shows a schematic representation of a second experimental setup with a component according to the invention,

FIG. 10 shows the result of a reference measurement with the experimental setup of FIG. 9 without the component according to the invention, and

FIG. 11 shows an attenuation measurement with the experimental setup of FIG. 9, including the component according to the invention.

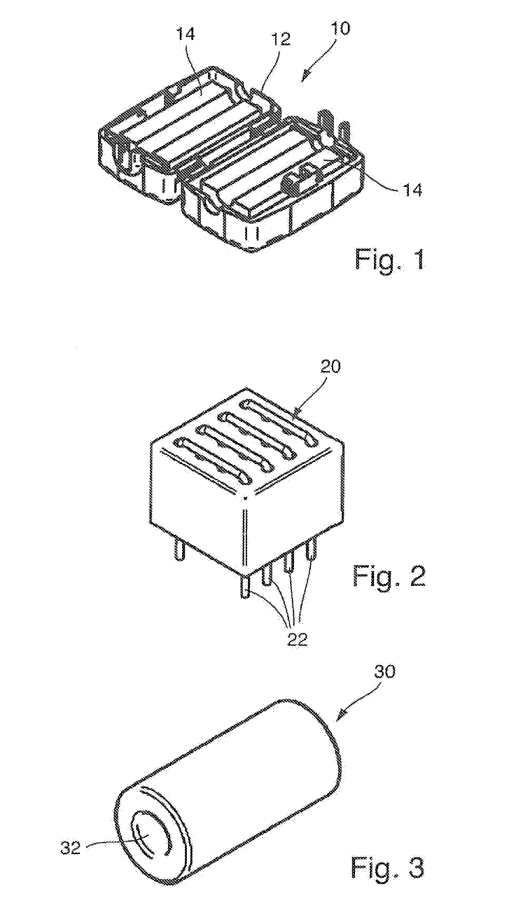

Components for electromagnetic interference suppression, as shown in FIGS. 1 to 4, are used in order to reduce the effect of undesired electromagnetic influences on electronic devices. Such influences may occur in cabling because of interference, in conductors, as well as by incidence of electromagnetic waves into the supply lines of the device.

### DETAILED DESCRIPTION

The most common current interference frequencies lie in the range of up to 1 GHz. Increasing miniaturisation is leading to ever smaller components and increasing frequencies in the provision, of the voltage supply by switching regulators. Currently, the working frequencies of the latter lie in the single-figure MHz range. In this case, however, harmonics may occur, which are manifested up to 250 MHz and need to be attenuated. An increase in the working frequency leads to a significant increase in the harmonies up to 1 GHz or more, which necessitates interference suppression of these emissions.

Furthermore wireless communication, with a high bandwidth entails very high frequencies. The working frequencies of Bluetooth, ZigBee, Wi-Fi and mobile communication with 2G, 3G, and 4G networks lie in the range of from 860 MHz to 5 GHz. Those emissions may be coupled into the electric module of the transmitter as well as into neighbouring modules, and cause interference.

The representation of FIG. 1 shows a component 10 for electromagnetic interference suppression according to a first embodiment. Component 10 has a housing 12, which is soft plastic and has two half-shells connected foldably to one another. Arranged within this housing 12, which in FIG. 1 is represented in the unfolded state, are two grooves 14, formed identically to one another. When the housing 12 is folded together, the two grooves come to lie on one another and together form a sleeve, through which a cable to be protected against interference can be passed.

The grooves 14 each consist of ferrite powder with a hexagonal crystal structure.

Iron oxide and strontium oxide or Sr carbonate are used as a basis for the hexagonal ferrite. One or more elements may he added as doping. These influence the frequency range of the absorption by controlled adjustment of the degree of substitution.

The hexagonal ferrite contained in the groove-shaped components 14 has a stoichiometry with the formula SrₓFe_{y}C_{12-y}O_{z}. The factor z may be 19 to have the formula SrₓFe_{y}C_{12-y}O₁₉. The factor x may lie between 0.9 and 1, and preferably x=1. y may lie between 0.1 and 0.8. A value y of between 0.2 and 0.5 is preferred. The best, measurement values were obtained with a value of 0.3<y<0.4, so that this value range for y is particularly preferred.

The element C is a transition metal from the periodic table. The term transition metal refers to chemical elements with atomic numbers of from 21 to 30, 39 to 48, 57 to 80 and 89 to 112. These, are therefore the elements Sc, Ti, V, Cr, Mn, Fe, Co, Ni, Cu and Zn in the 4^{th} period of the periodic table of elements. In the 5^{th} period, these are the elements Y, Zr, Nb, Mo, Tc, Ru, Rh, Pd, Ag, Cd and La.

In the 6^{th} period, these are the elements Lu, Hf, Ta, W, Re, Os, Ir, Pt, Au, Hg and Ac. In the 7th period, these the elements Lr, Rf, Db, Sg, Bh, Hs, Mt, Ds, Rg and Cn. In the lists above, the elements with atomic numbers 58 to 71 and the elements with atomic numbers 90 to 102 are not, mentioned, although these may be readily found from the periodic table of elements.

Selection of the element C from the 4^{th} or 5^{th} period of the periodic table is particularly preferred.

Preferably, the element c is selected from the 4^{th}, 9^{th} or 10^{th} group of the periodic table of elements. The 4^{th} group is particularly preferred in this case.

In combination with selection of the element C from the 4^{th} or period, the element C is therefore either Ti or Zr.

The groove-shaped components 14 are produced from a ferrite powder by dry-pressing and then sintering the ferrite powder. In this case, pre-pressing of the ferrite powder and subsequent sintering at a temperature of between 1100° C. and 1400° C. may be carried out. When an external magnetic field is applied to the ferrite powder, in contrast to hard magnets with a comparable crystal structure, alignment of the individual grains does not take place. In this way, during pressing of the ferrite powder, isotropic electromagnetic properties of the components are achieved, and production may be carried out by the dry-pressing method. Since the Weiss domains are statistically distributed, there is no preferential direction of the attenuation properties in the finished component.

The production of the ferrite powder is carried out by means of a mixed oxide route. In this case, powders of Sr carbonate or Sr oxide are mixed with Fe oxide and the oxides of the dopants. As mentioned, it is particularly preferred for Ti or Zr to be used as dopants. Ti oxide and/or Zr oxide would therefore be introduced into the mixture. The resulting mixture is thereupon calcined or fired, and a solid-state reaction, in which the hexagonal crystal structure of the ferrite is formed; takes place at temperatures of from 1100° C. to 1400° C.

Subsequently, the grain size of the hexagonal ferrite obtained may be adjusted by grinding, Advantageously, a grain size of between 50 μm and 100 μm is adjusted. For the grinding, ball mills may for example be used. A grain size of between 75 μm and 100 μm has been found to be advantageous in relation to the properties for electromagnetic interference suppression. By the grain boundaries, the crystal lattice of the ferrite is distorted and its crystal field is disturbed, which has a negative effect on the absorption of electromagnetic radiation. A large grain size of between 75 μm and 100 μm counteracts this, and allows optimum effectiveness of the material for the attenuation of electromagnetic radiation.

As already mentioned, the ferrite powder obtained is subsequently sintered in order to produce the groove-shaped components 14. During this, the ferrite powder is compacted and a final grain size is adjusted.

The representation of FIG. 2 shows another embodiment of a component 20 according to the invention. The component 20 has the shape of a block of sintered ferrite powder, the block having passage bores for lines 22 to be inserted through.

The representation of FIG. 3 shows another component 30 according to the invention, which has a sleeve shape. The component 30 has a central passage bore 32, through which a line can be passed.

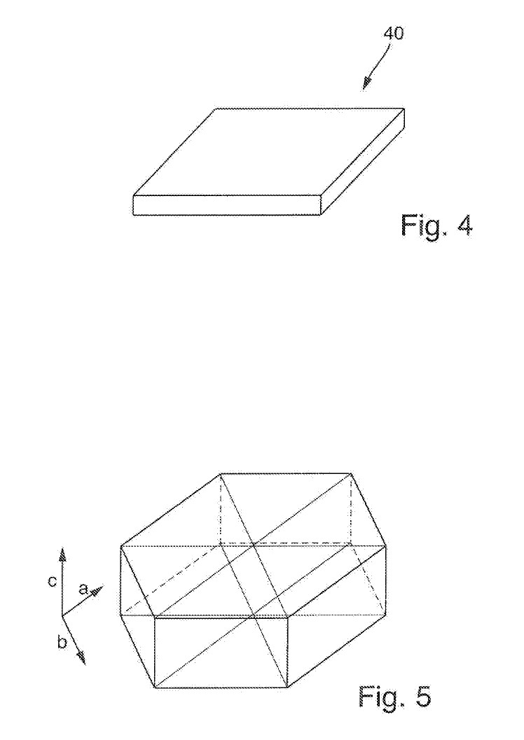

The representation of FIG. 4 shows another component 40 according to the invention, which has a plate shape. The component 40 may be used for two-dimensional interference reduction on integrated circuits, housings or ribbon cables. For example, it is also possible to place an integrated circuit between two components 40 so as to achieve particularly effective electromagnetic interference suppression.

The representation of FIG. 5 schematically shows the grain structure of the ferrite powder which is used for producing the components according to the invention. Due to the hexagonal crystal structure and its preferred growth directions, the grains of the ferrite powder have the shape of hexagonal platelets. The edge length of these crystallites in the a and b directions is greater than in the c direction. Alignment of these hexagonal platelets in the ferrite powder as a result of application of an external magnetic field does not take place, in great contrast to hard magnets with a comparable: crystal structure. For this reason, the ferrite powder, and therefore also the components produced therefrom, have isotropic electromagnetic properties. During production of the components, the ferrite powder may therefore be processed by a dry-pressing method. Because of the statistical distribution of the Weiss domains in the individual grains, there is no preferential direction of the attenuation properties.

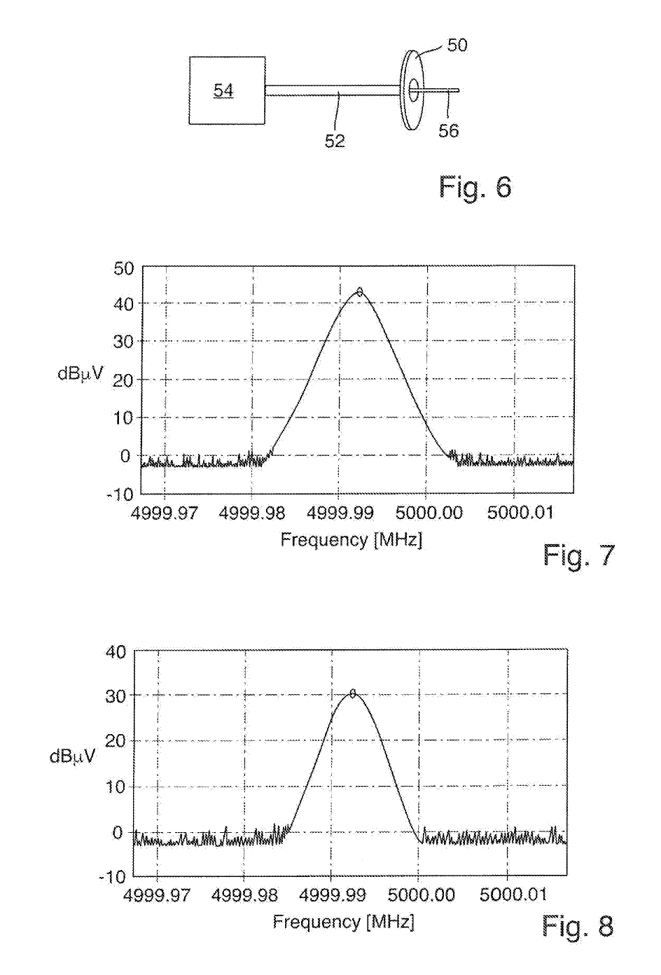

The representation of FIG. 6 schematically shows an exemplary experimental setup which was used to determine the attenuation properties of a component 50 according to the invention that has the shape of a flat ring. A radiofrequency cable 52 is connected on the one hand to a signal generator 54 and on the other hand to an antenna 56. In order to determine the line attenuation by the annular component 50, a measurement of the electromagnetic radiation of the experimental setup of FIG. 6 was carried out in an EMC chamber at a distance of 1.5 m from the antenna 56.

Through the screened RF cable, interference is coupled in by means of the signal generator 54. By the unterminated antenna 56, this interference is imitated in an EMC chamber (not represented). A reference measurement is carried out without the annular component 50. This reference measurement then gives the maximum interference emission.

If, as represented in FIG. 6, the component 50 is slid over the antenna 56 and arranged perpendicularly to the radiofrequency line 52 and the antenna 56 at the junction between the radiofrequency line 52 and the antenna 56, a part of the interference coupled in by the signal generator 54 is attenuated and there is less interference emission. A difference between the measurements with and without the component 50 thus gives a measure of the attenuation by the component 50 of the interference coupled in.

The representation of FIG. 7 shows the results of the reference measurement without the component 50, i.e. the ferrite ring. The representation of FIG. 8, on the other hand, shows the result of the measurement with the component 50. As the difference of the measurement results of FIG. 7 and FIG. 8, an attenuation of 12.4 dB at 5 GHz is for example found. Not represented in the diagrams of FIGS. 7 and 8 is a measurement value at 4 GHz. In that case, with the experimental setup of FIG. 6, an attenuation of up to 9.3 dB is achieved.

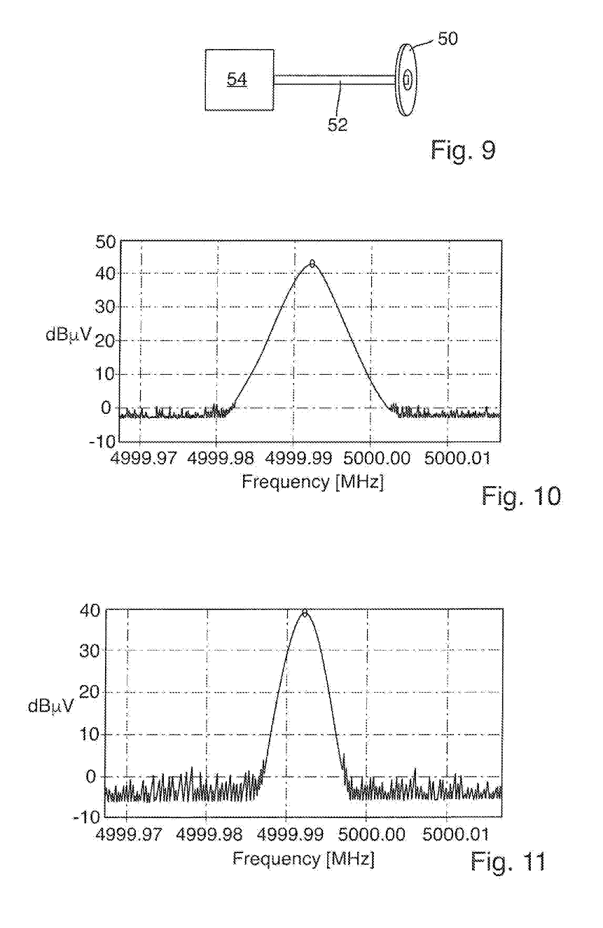

The representation of FIG. 9 schematically shows a further experimental setup for determining the attenuation of the component 50, i.e. the ferrite ring. The signal generator 54 is again connected to the radiofrequency line 52, wherein the radiofrequency line 52 ends without termination at the passage opening of the component 50. Using the radiofrequency cable 52 without any termination means that a full mismatch is formed. A reference measurement is again carried out without the component 50, and a further measurement with the component 50 in the position is represented in FIG. 9. The difference between these two measurements with and without the component 50, i.e. the ferrite ring, then gives a measure of the attenuation by the component 50 of the interference coupled in by the signal generator 54, The measurement is again carried out in an EMC chamber at a distance of 1.5 m from the end of the radiofrequency line 52.

FIG. 10 gives the result of a reference measurement without the component 50, and FIG. 11 shows the result with the experimental setup of FIG. 9, including the component 50.

As revealed by the difference between the two measurements, it was possible to achieve attenuation of up to 14.9 dB at a frequency of 5 GHz.

1. Component for electromagnetic interference suppression, consisting of ferrite powder with a hexagonal crystal structure, characterized in that the ferrite powder has the composition SrₓFe_{y}C_{12-y}O_{z}, C being a transition metal from the periodic table of elements.

2. Component according to claim 1, characterised in that C is a transition metal from the fourth, fifth, ninth or tenth group of the periodic table of elements.

3. Component according to claim 1, characterised in that x lies between 0.9 and 1, and is in particular 1.

4. Component according to claim 1, characterized in that y lies between 0.1 and 0.8, in particular between 0.2 and 0.5, and is preferably between 0.3 and 0.4.

5. Component according to claim 1, characterized in that a grain size of the ferrite powder lies between 50 μm and 100 μm.

6. Component according to claim 5, characterized in that the grain size lies between 75 μm and 100 μm.

7. Component according to claim 1, characterized in that the component is formed as a half-shell, plate, sleeve, ring, or as a block with passage openings.

8. Method for producing a component for electromagnetic interference suppression according to one of the preceding claims, characterized by production of the ferrite powder from a mixture of Sr carbonate or Sr oxide, Fe oxide and oxides of transition metals.

9. Method according to claim 8, characterized by heating of the mixture to a temperature of between 1100° C. and 1400° C.

10. Method according to claim 8, characterized by grinding of the calcined mixture in order to adjust the grain size.

11. Method according to claim 10, characterized by adjustment of the grain size to a value of between 50 μm and 100 μm.

12. Method according to claim 11, characterized by adjustment of the grain size to a value of between 75 μm and 100 μm.

13. Method according to claim 8, characterized by dry-pressing of the ferrite powder in order to produce a component.
